(19) United States
(12) Patent Application Publication
(10) Pub. No.: US 2014/0167781 A1
(43) Pub. Date: Jun. 19, 2014

(54) SENSOR DEVICE

(71) Applicants: Satoshi Asano, Tokyo (JP); Masahiro Matsumoto, Tokyo (JP); HIroshi Nakano, Tokyo (JP); Keiji Hanzawa, Hitachinaka-shi (JP)

(72) Inventors: Satoshi Asano, Tokyo (JP); Masahiro Matsumoto, Tokyo (JP); HIroshi Nakano, Tokyo (JP); Keiji Hanzawa, Hitachinaka-shi (JP)

(73) Assignee: Hitachi Automotive Systems, Ltd.

(21) Appl. No.: 14/235,933

(22) PCT Filed: Aug. 3, 2011
(86) PCT No.: PCT/JP2011/004377

§ 371 Date: Jan. 29, 2014

(51) Int. Cl. G01R 1/18; G01D 7/00

(52) U.S. Cl. CPC G01R 1/18; G01D 7/00
USPC 324/609

(57) ABSTRACT

An objective of the present invention is to provide a sensor device with an increased accuracy. In order to achieve the objective, provided is a sensor device includes: an external terminal 2 to which an external device is connected; a ground terminal 3 connected to the ground; an internal circuit 4 that generates a sensor output signal; and a protection circuit 5 having a resistive element 6 and a capacitative element 7 between the external terminal and the internal circuit, in which the capacitative element is formed of a pair of electrodes having different conductivities from each other and a lower-conductive electrode 7a of the electrodes which has a smaller conductivity is connected to the external terminal and the internal circuit.

### TECHNICAL FIELD

The present invention relates to sensor devices that detect physical quantities, and more particularly relates to sensor devices for vehicles that detect physical quantities, such as flow sensors, pressure sensors, acceleration sensors, and angular velocity sensors.

### BACKGROUND ART

Recently, various types of sensor devices such as flow sensors, pressure sensors, acceleration sensors, and angular velocity sensors have been used in order to increase the fuel consumption and the stability of vehicles. For these sensor devices, excellent detection accuracies and high operational reliabilities are required. On the other hand, peripheral devices are becoming more and more electronic, and the electromagnetic noise environment of the sensor devices is becoming more and more severe every year.

In order to deal with the electromagnetic noise, protection circuits including low-pass filters and lead-through capacitors formed of lead parts and packaged parts have been used. The parts and the assembly of the protection circuits have, however, become more and more expensive, which results in increased manufacturing costs.

Under the above circumstances, the issue of noise has been addressed by integrating the protection circuits on semiconductor substrates.

Integrated protection circuits, however, are disadvantageous in that parasitic components of resistances or capacities easily generate in wirings or elements and expected characteristics for blocking noise cannot be obtained.

The following is an example of the objectives.

FIG. 13 illustrates an example of a layout drawing of a protection circuit before application of the present invention. FIG. 14 illustrates an equivalent circuit of the protection circuit illustrated in FIG. 13.

The protection circuit in FIG. 13 includes a protection circuit 5 and a ground terminal 3. The protection circuit 5 includes a resistive element 6 and a capacitative element 7 and is provided between an external terminal 2 and an internal circuit 4.

The equivalent circuit in FIG. 14 includes parasitic resistors R1 to R7 and parasitic inductances L1 to L7 associated with wirings, in addition to the resistive element 6 (Rf) and the capacitative element 7 (Cf). The values of the element constants of the resistive element 6 (Rf) and the capacitative element 7 (Cf) and the values of the parasitic components R1 to R7 and L1 to L7 for the protection circuit in FIG. 14 are as follows. While the values of the parasitic components are determined by the shapes and physical properties of the wirings and the elements and are not therefore limited to the ones indicated below, the parasitic components in present invention have the fixed values as indicated below for easy descriptions.

The resistive element 6 (Rf): 40Ω

The capacitative element 7 (Cf): 400 pF

R1 to R7: 1Ω each

L1 to L7: 100 pH each

FIG. 16(a) is a Bode diagram in a case where the external terminal 2 is an input and the intermediate point between the parasitic inductance L6 and the internal circuit 4 is an output in the protection circuit in FIG. 14. For comparison, FIG. 16(b) is a Bode diagram for an ideal protection circuit without any parasitic components. The “ideal” protection circuit without any parasitic components herein specifically means a protection circuit having the following element constants in FIG. 14.

The resistive element 6 (Rf): 40Ω

The capacitative element 7 (Cf): 400 pF

R1 to R7: 0Ω each

L1 to L7: 0 H each

FIGS. 16(a) and 16(b) show that the protection circuit in FIG. 14 exhibits frequency characteristics different from those of the ideal protection circuit in FIG. 14. Specifically, difference in the characteristics therebetween becomes notable in a band of approximately 20 MHz or larger, and a noise attenuation effect of only approximately −17 dB can be obtained in a band of around 1 GHz where noise attenuation effects are supposed to be the largest.

The studies having been conducted so far indicate that harmful impedance 201 made of the parasitic components R3 to R5 and L3 to L5 is the main cause of the difference in the frequency characteristics between the protection circuit in FIG. 14 and the ideal protection circuit.

The harmful impedance 201 will be hereinafter used to generally refer to the parasitic resistors and the parasitic impedances which obstruct noise escaping to the ground terminal 3. Further, protective impedance 200 will be used to generally refer to the parasitic resistors and the parasitic impedances which increase the time constant of the protection circuit 5 determined from the resistive element 6 and the capacitative element 7.

Since there is only the capacitative element 7 (Cf) between point A and the ground terminal 3 in FIG. 14 in a case of the ideal protection circuit without the harmful impedance 201, impedance Zcf between point A and the ground terminal 3 is represented by an expression of Zcf[Ω]=1÷(2×π×f[Hz]×Cf[F]) and is in inverse proportion to the frequency f[Hz]. The value of Zcf therefore becomes smaller as the frequency becomes higher, and noise easily escapes to the ground terminal 3.

On the other hand, since there are the capacitative element 7 (Cf) and the harmful impedance 201 between point A and the ground terminal 3 in FIG. 14 in a case of the protection circuit which suffers the harmful impedance 201, the impedance Zcf between point A and the ground terminal 3 is represented by an expression of Zcf[Ω]=1÷(2×π×f[Hz]×Cf[F])+(2×n×f[Hz]×(L3+L4+L5) [H])+(R3+R4+R5). In the expression, there are a term in inverse proportion to the frequency f[Hz], a term in proportion to the frequency f[Hz], and a term not correlating with the frequency f[Hz]. Since the second term is dominant when the frequency is not smaller than fc, the higher the frequency is, the larger the value of Zcf is, and noise becomes more difficult to escape to the ground terminal 3.

The frequency fc is represented by an expression of fc[Hz]=1÷(2×π×((L3+L4+L5) [H]×Cf[F])0.5).

In view of the above, PTL 1 discloses a technique of improving the noise blocking characteristics of the protection circuit by substantially reducing the harmful impedance 201.

The technique that PTL 1 discloses is characterized in that “a low-pass filter including a resistor and a capacitor is provided between a power source pad and an internal circuit in an integrated circuit, and that the lengths and the widths of wirings are selected so that the relation of Za+Zk≦Zc is constantly satisfied in a frequency band of electromagnetic noise to be cut, where Za denotes a parasitic impedance resulting from a parasitic resistance component Ra and a parasitic inductance component La of a wiring connecting the power source pad and the capacitor together, Zk denotes a parasitic impedance resulting from a parasitic resistance component Rk and a parasitic inductance component Lk of a wiring connecting the capacitor and a ground pad together, and Zc denotes an impedance resulting from a capacitance component of the capacitor” according to the quoted sentences of PTL 1. Further, it discloses an expression for calculation for obtaining the parasitic inductance from size information including the wiring lengths, wiring widths, wiring thicknesses, etc. as a means for determining Za and Zk.

Moreover, according to PTL 1, with the use of the technique disclosed therein, it is possible to reduce the parasitic impedance of the wiring connecting the power source pad and the capacitor together and the parasitic impedance of the wiring connecting the ground pad and the capacitor without affecting the impedance of the capacitor, and improve the effect of allowing noise to escape to the ground.

### CITATION LIST

### Patent Literatures

PTL 1: JP 2006-310658 A

### SUMMARY OF INVENTION

### Technical Problem

However, since the parasitic inductances of the wirings in the integrated circuit are affected by not only the sizes of the wirings but also layouts of the wirings, an accurate parasitic inductance is difficult to determine from the calculation expression disclosed in PTL 1. Hence, every time the circuit is modified, parasitic components need to be calculated, and the sizes and layouts of the wirings need to be adjusted. This procedure increases the number of design processes and therefore makes it difficult to perform rapid designing. Further, in the invention disclosed in PTL 1, no consideration is given to parasitic resistances or electrodes of the capacitative element.

An objective of the present invention is to provide a sensor device with an increased detection accuracy.

### Solution to Problem

In order to solve the above problems, a sensor device includes: an external terminal to which an external device is connected; a ground terminal connected to the ground; an internal circuit that generates a sensor output signal; and a protection circuit having a resistive element and a capacitative element between the external terminal and the internal circuit, in which the capacitative element is formed of a pair of electrodes having different conductivities from each other and a lower-conductive electrode of the electrodes which has a smaller conductivity than the other electrode is connected to the external terminal and the internal circuit.

### Advantageous Effects of Invention

According to the present invention, a sensor device with an increased detection accuracy can be provided.

### BRIEF DESCRIPTION OF DRAWINGS

FIG. 1(a) is a layout drawing illustrating a protection circuit according to First Embodiment, and FIG. 1(b) is a cross-sectional view of the protection circuit taken along line A-A′.

FIG. 2 is a layout drawing illustrating a protection circuit according to Second Embodiment.

FIG. 3 is a layout drawing illustrating a protection circuit according to Third Embodiment.

FIG. 4 is a cross-sectional view of a protection circuit according to Fourth Embodiment taken along line A-A′.

FIG. 5 is a layout drawing illustrating a protection circuit according to Fifth Embodiment.

FIG. 6 is a cross-sectional view of a protection circuit according to Sixth Embodiment taken along line A-A′.

FIG. 7 is a cross-sectional view of a protection circuit according to Seventh Embodiment taken along line A-A′.

FIG. 8 is a layout drawing illustrating a protection circuit according to Eighth Embodiment.

FIG. 9 is a layout drawing illustrating a protection circuit according to Ninth Embodiment.

FIG. 10 is a layout drawing illustrating a protection circuit according to Tenth Embodiment.

FIG. 11 is a layout drawing illustrating a protection circuit according to Eleventh Embodiment.

FIG. 12 is a layout drawing illustrating a protection circuit according to Twelfth Embodiment.

FIG. 13 is a layout drawing illustrating a protection circuit before application of the present invention.

FIG. 14 illustrates an equivalent circuit of the protection circuit before application of the present invention.

FIG. 15 illustrates an equivalent circuit of the protection circuit according to First Embodiment.

FIG. 16 is a Bode diagram of the protection circuit before application of the present invention.

FIG. 17 illustrates respective output waveforms of the protection circuit according to First Embodiment and the protection circuit before application of the present invention.

FIG. 18 is a block schematic diagram of a flow sensor device.

### DESCRIPTION OF EMBODIMENT

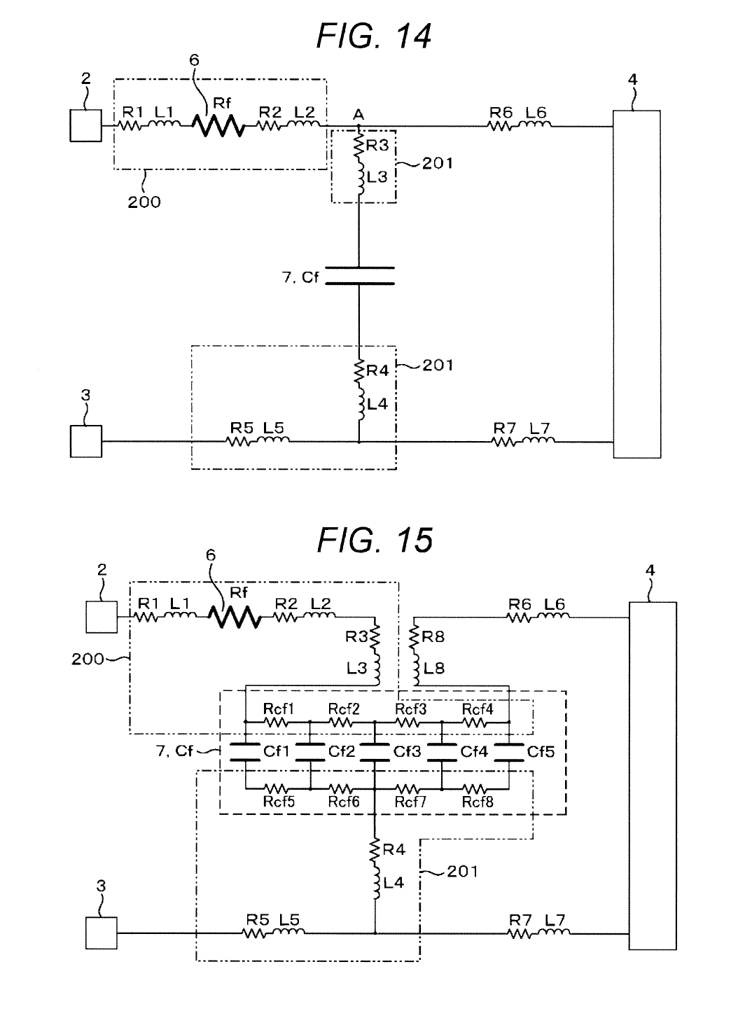

The inventors of the present invention have found out in their studies that difference in frequency characteristics between the protection circuit in FIG. 14 and the ideal protection circuit is caused by not only the parasitic components R3 to R5 and L3 to L5 but also parasitic resistances of electrodes of the capacitative element 7 (Cf). Embodiments for carrying out the present invention will be hereinafter described. It should be noted that while the present invention will be described with reference to embodiments in which the invention is applied to flow sensor devices for vehicles, the invention is not limited to the flow sensor devices for vehicles and may be applied as well to other general sensor devices that detect physical quantities, such as pressure sensors, acceleration sensors, and angular velocity sensors.

### First Embodiment

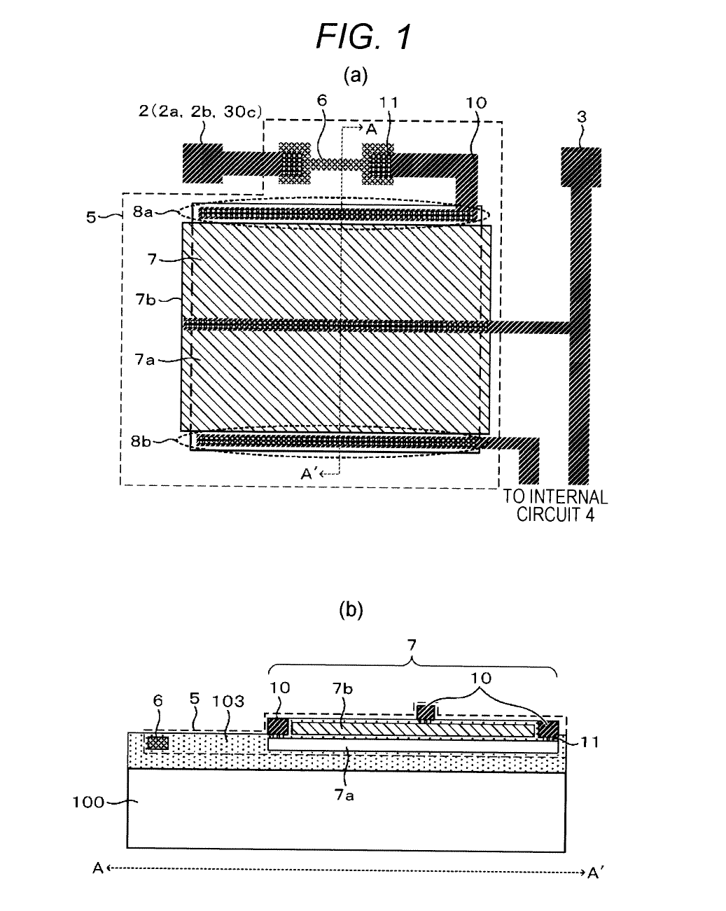

A flow sensor according to First Embodiment of the present invention will be described with reference to FIGS. 1 and 14 to 18.

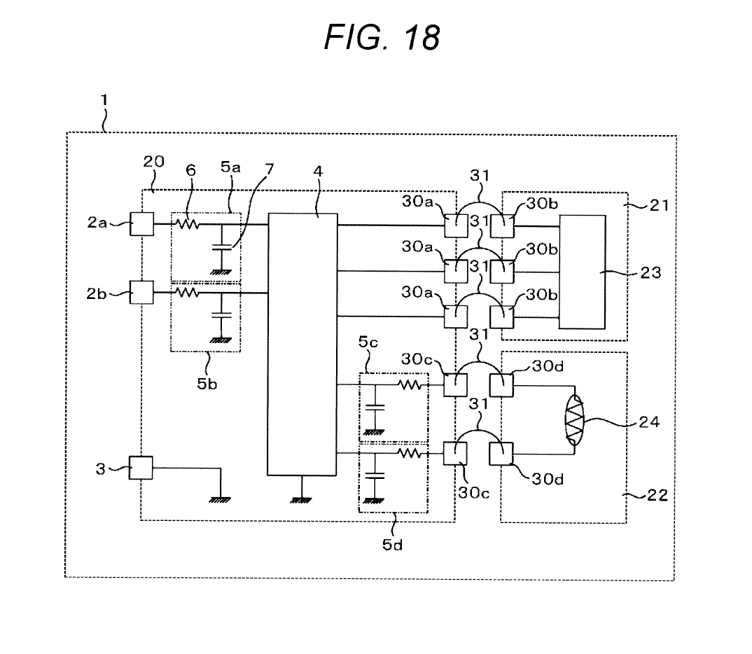

The structure of the flow sensor device according to First Embodiment will be described first with reference to FIG. 18.

A flow sensor device 1 according to First Embodiment of the present invention includes an LSI 20, a sensor element 21, and a temperature sensor 22. The LSI 20 is connected to an external device by a power source terminal 2a, a sensor output terminal 2b, and a ground terminal 3. Further, the LSI 20 includes an internal circuit 4 that processes signals acquired from the sensor element 21 and the temperature sensor 22 and generate sensor output signals, and a protection circuit 5 (5a to 5d) that protects the internal circuit 4 from noise incoming from the outside. A protection circuit 5a is arranged between the power source terminal 2a and the internal circuit 4, a protection circuit 5b is arranged between the sensor output terminal 2b and the internal circuit 4, and protection circuits 5c and 5d are arranged between a bonding pad 30c and the internal circuit 4.

The sensor element 21 has a detection section 23 and a bonding pad 30b. The bonding pad 30b is connected to a bonding pad 30a of the LSI 20 via a bonding wire 31 so that the bonding pads 30a and 30b are electrically connected.

The temperature sensor 22 has a thermister 24 and a bonding pad 30d. The bonding pad 30d is connected to a bonding pad 30c of the LSI 20 via the bonding wire 31 so that the bonding pads 30c and 30d are electrically connected.

Subsequently, the structure of the protection circuit 5 of the flow sensor device according to First Embodiment will be described with reference to FIGS. 1(a) AND 1(b).

The protection circuit 5 is formed on an insulating film 103 over a semiconductor substrate 100.

The protection circuit 5 includes the resistive element 6 and the capacitative element 7, and the capacitative element 7 has a lower-conductive electrode 7a and a higher-conductive electrode 7b having different conductivities from each other.

The lower-conductive electrode 7a having a smaller conductivity is formed using polysilicon (Si) having a sheet resistance of 100 Ω/square, for example, and the higher-conductive electrode 7b having a larger conductivity is formed using metal silicide having a sheet resistance of 10 Ω/square, for example

The lower-conductive electrode 7a is electrically connected to the external terminal 2 such as the power source terminal 2a, the sensor output terminal 2b, or the bonding pad 30c, and the internal circuit 4. The higher-conductive electrode 7b having a higher conductivity is electrically connected to the ground terminal 3.

Further, the lower-conductive electrode 7a has a first connection region 8a and a second connection region 8b with a space interposed between the first and second connection regions 8a and 8b. The lower-conductive electrode 7a ensures an electrical continuity with the external terminal 2 in the first connection region 8a and ensures an electrical continuity with the internal circuit 4 in the second connection region 8b.

The resistive element 6 is formed using metal silicide, for example, and a wiring 10 electrically connecting the elements together is formed using aluminum (Al), for example. Furthermore, in the connection parts where the wiring 10 is connected to the resistive element 6 and the capacitative element 7, electric connection is ensured by proving a plurality of contacts 11.

With the above structure, the equivalent circuit of the protection circuit 5 in the flow sensor device according to First Embodiment is as shown in FIG. 15.

The following is the element constants of the resistive element 6 (Rf) and the capacitative element 7 (Cf), and the parasitic components R1 to R8 and L1 to L8 in the equivalent circuit. Herein, Rcf1 to Rcf8 denote resistances of electrodes of the capacitative element 7 (Cf), and Cf1 to Cf5 denote capacities of the capacitative element 7 (Cf).

It is to be noted that while the values of the parasitic components are determined by the shapes and physical properties of the wirings and the elements and are not therefore limited to the ones indicated below, the parasitic components in present invention have the fixed values as indicated below for easy descriptions.

The resistive element 6 (Rf): 40Ω

The capacitative element 7 (Cf): 400 pF

R1 to R8: 1Ω each

L1 to L8: 100 pF each

Rcf1 to Rcf4: 25Ω each

Rcf5 to Rcf8: 2.5Ω each

Cf1 to Cf5: 80 pF each

Subsequently, the effects of the flow sensor device according to First Embodiment will be described.

A first effect is that each of R2 to R3 and L2 to L3 acts as the protective impedance 200 in a manner that the lower-conductive electrode 7a ensures an electrical continuity with the external terminal 2 in the first connection region 8a and ensures an electrical continuity with the internal circuit 4 in the second connection region 8b. In other words, the time constant determined from the protective impedance 200 and the capacitative element 7 (Cf) is increased and the protection circuit 5 can attenuate noise to a larger extent.

The second effect is that each of Rcf1 to Rcf4 acts as the protective impedance 200 in a manner that the first and second connection regions 8a and Sb are provided with a space in between. Hence, the time constant determined from the protective impedance 200 and the capacitative element 7 (Cf) is increased and the protection circuit 5 can attenuate noise to a larger extent.

The third effect is that harmful impedance 201 resulting from Rcf5 to Rcf8 is reduced in a manner that the higher-conductive electrode 7b is electrically connected to the ground terminal 3. That is, the difficulty is reduced in allowing noise to escape to the ground terminal 3 and the protection circuit 5 can attenuate noise to a larger extent.

The fourth effect is that the values of Rcf1 to Rcf4 and the protective impedance 200 are increased in a manner that the lower-conductive electrode 7a is electrically connected to the external terminal 2 and the internal circuit 4. Hence, the time constant determined from the protective impedance 200 and the capacitative element 7 (Cf) is increased and the protection circuit 5 can attenuate noise to a larger extent.

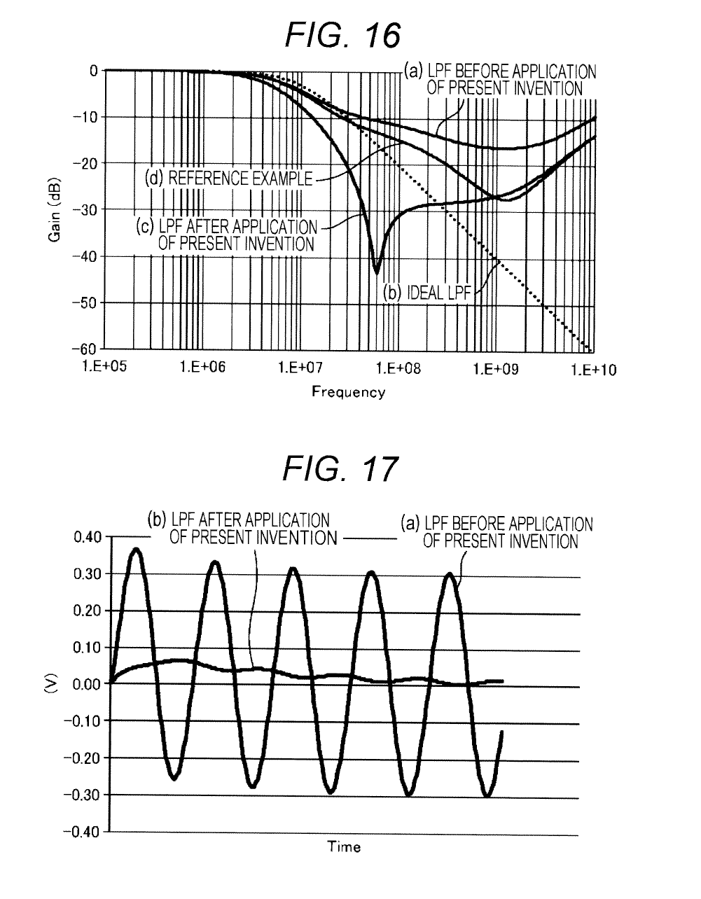

The flow sensor device according to First Embodiment exhibits the frequency characteristics shown in FIG. 16(c) by the first to fourth effects. FIG. 16(c) is a Bode diagram in a case where the external terminal 2 is an input and the intermediate point between the parasitic inductance L6 and the internal circuit 4 is an output in FIG. 15.

For comparison, FIG. 16(d) is a Bode diagram in a case where the external terminal 2 is an input and the intermediate point between the parasitic inductance L6 and the internal circuit 4 is an output when the respective conductivities of the lower-conductive electrode 7a and the higher-conductive electrode 7b are switched between the lower-conductive electrode 7a and the higher-conductive electrode 7b in FIG. 15. Specifically, Rcf1 to Rcf4 are 2.5Ω each and Rcf5 to Rcf8 are 25Ω each.

From FIG. 16(c), it is found out that the protection circuit 5 according to First Embodiment exhibits more excellent properties than an existing protection circuit 5 in a frequency band of not smaller than approximately 2 MHz. Further, from FIG. 16(d), it is found out that although the protection circuit 5 as a reference example exhibits more excellent properties than an existing protection circuit 5 in a frequency band of not smaller than approximately 20 MHz, it has less improved effects than the protection circuit 5 according to First Embodiment in a frequency band of in particular 2 MHz to 1 GHz.

FIG. 17 illustrates output waveforms when a similar sine-wave signal (60 MHz, amplitude of ±1 V) simulating the high frequency noise is applied to the protection circuit 5 according to First Embodiment and the existing protection circuit 5.

FIG. 17 shows that the protection circuit 5 according to First Embodiment attenuates noise to a larger extent than the existing protection circuit 5.

Advantages of the flow sensor device according to First Embodiment will be described based on the above findings.

A first advantage is that there is much room to be ensured for further improvement of the high frequency characteristics of the protection circuit 5 in a manner that the lower-conductive electrode 7a is electrically connected to the external terminal 2 and the internal circuit 4 and the higher-conductive electrode 7b is electrically connected to the ground terminal 3. The “room” in this context refers to the difference between (a) to (c) in FIG. 16 in the flow sensor device according to First Embodiment, for example.

The second advantage is that the first effect serves to allow the protection circuit 5 to attenuate noise to a larger extent.

The third advantage is that the second effect serves to allow the protection circuit 5 to attenuate noise to a larger extent.

The fourth advantage is that the third effect serves to allow the protection circuit 5 to attenuate noise to a larger extent.

The fifth advantage is that the fourth effect serves to allow the protection circuit 5 to attenuate noise to a larger extent.

The sixth advantage is that the filter characteristics can be improved without increasing the number of design processes since the calculation as disclosed in PTL 1 is not required.

In the flow sensor device to which the technique of the present invention typified by First Embodiment is applied, the physical arrangement of the protection circuit 5 is not particularly limited to between the external terminal 2 and the internal circuit 4 and may be feely selected as long as signals can reach the internal circuit 4 from the external terminal 2 via the protection circuit 5.

Further, the materials of the lower-conductive electrode 7a and the higher-conductive electrode 7b may be the same if the electricity conductivity of the lower-conductive electrode 7a is relatively smaller than that of the higher-conductive electrode 7b.

Moreover, the resistive element 6 does not need to be formed of a material different from the materials of the wiring 10 and the capacitative element 7, and the resistive element 6 in FIGS. 1(A) AND 1(B) may be formed of the wiring 10 designed to have a smaller width or of a parasitic resistance component of the wiring 10 designed to have a larger length, for example.

In addition, the capacitative element 7 does not need to be formed of a material different from the materials of the wiring 10 and the resistive element 6, and the capacitative element 7 in FIGS. 1(A) AND 1(B) may be formed of the wiring 10 designed to have a larger width or of an inter-wiring capacitance between two wirings opposed to each other, for example.

### Second Embodiment

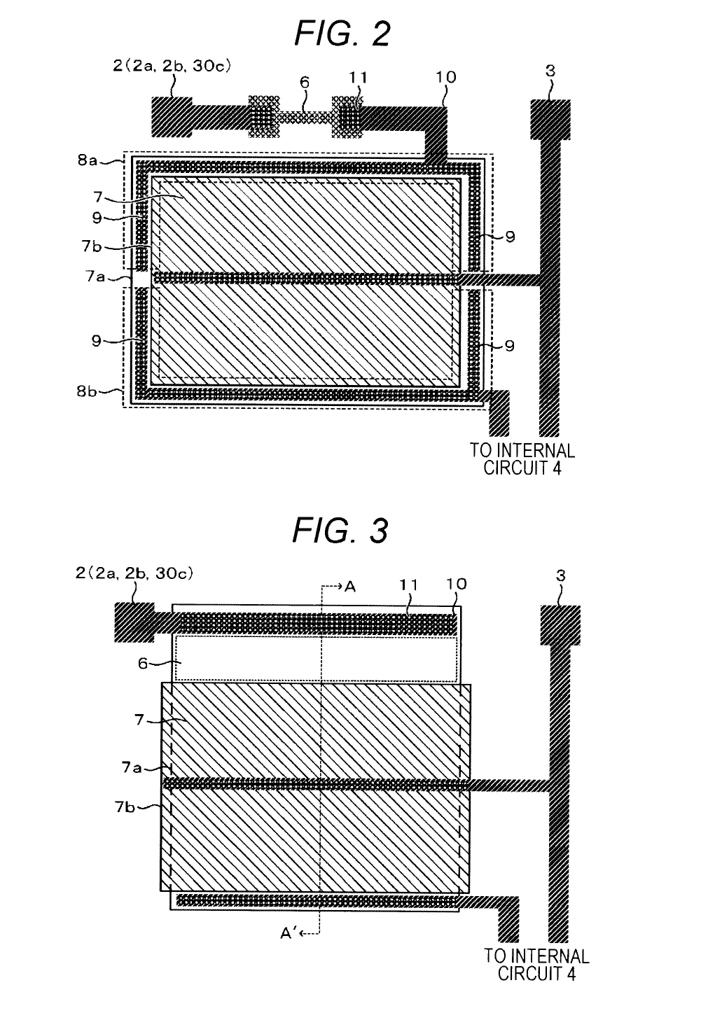

Subsequently, a flow sensor device according to Second Embodiment will be described with reference to FIG. 2. FIG. 2 is a layout drawing illustrating a protection circuit 5 of the flow sensor device according to Second Embodiment. The same parts as in the previous embodiment will be respectively denoted by the same reference numbers as in the previous embodiment, and will not be described below.

The flow sensor device according to Second Embodiment of the present invention is characterized in that the sensor device has a configuration, in addition to the configuration of the flow sensor device according to First Embodiment, in which the first connection region 8a has an extension part 9 extending toward the second connection region 8b and the second connection region 8b has an extension part 9 extending toward the first connection region 8a.

Next, the effects of the flow sensor device according to Second Embodiment will be described.

The first to third effects are similar to the first, third, and fourth effects in First Embodiment.

The fourth effect is that a substantially uniform electrical field is formed between the lower-conductive electrode 7a and the higher-conductive electrode 7b in a high frequency band in a manner that the first connection region 8a has an extension part 9 extending toward the second connection region 8b and the second connection region 8b has an extension part 9 extending toward the first connection region 8a.

Further, advantages of the flow sensor device according to Second Embodiment will be described.

The first to fifth advantages are similar to the first, second, fourth, fifth, and sixth advantages in First Embodiment.

The sixth advantage is that the fourth effect serves to allow the circuit operation of the protection circuit 5 to be closer to the operation of the lumped constant circuit. In other words, the first to fifth advantages can be enjoyed in a wider band.

### Third Embodiment

A flow sensor device according to Third Embodiment of the present invention will be described next below with reference to FIG. 3. FIG. 3 is a layout drawing illustrating a protection circuit 5 of the flow sensor device according to Third Embodiment. The same parts as in the previous embodiments will be respectively denoted by the same reference numbers as in the previous embodiments, and will not be described below.

The flow sensor device according to Third Embodiment is characterized in that the flow sensor device includes a resistive element 6 instead of the resistive element of the flow sensor device according to First Embodiment, which is formed in the same layer as a layer where the lower-conductive electrode 7a is formed and is designed to communicate with the lower-conductive electrode 7a.

Further, the effects of the flow sensor device according to Third Embodiment will be described.

The first to fourth effects are similar to those in First Embodiment.

The fifth effect is that the heat radiation area and the heat capacity of the resistive element 6 are increased and the acceptable dissipation of the resistive element 6 can be improved since the resistive element 6 is formed in the same layer as a layer where the lower-conductive electrode 7a is formed and is designed to communicate with the lower-conductive electrode 7a.

Further, advantages of the flow sensor device according to Third Embodiment will be described.

The first to sixth advantages are similar to those in First Embodiment.

The seventh advantage is that the fifth effect serves to prevent the resistive element 6 from fusing due to Joule heat and the protection circuit 5 can thus have a reinforced reliability.

### Fourth Embodiment

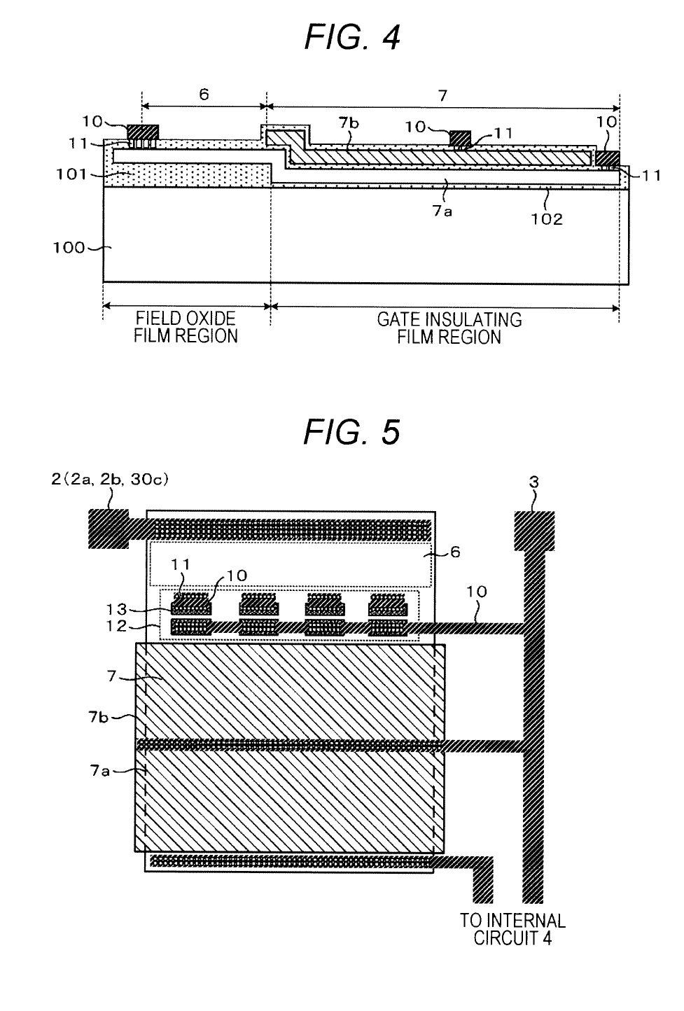

A flow sensor device according to Fourth Embodiment of the present invention will be described next below with reference to FIG. 4. FIG. 4 is a cross-sectional view of a protection circuit 5 of the flow sensor device according to Fourth Embodiment taken along line A-A′. The same parts as in the previous embodiments will be respectively denoted by the same reference numbers as in the previous embodiments, and will not be described below.

The flow sensor device according to Fourth Embodiment of the present invention is characterized in that the resistive element 6 of the flow sensor device according to Third Embodiment is formed on a field oxide film 101, and part or all of the capacitative element 7 is arranged on a gate insulating film 102.

Further, the effects of the flow sensor device according to Fourth Embodiment will be described.

The first to fifth effects are similar to those in Third Embodiment.

The sixth effect is that the insulating film between the resistive element 6 and the semiconductor substrate 100 can be prevented from breaking since the resistive element 6 is formed on the field oxide film 101.

A seventh effect is that a capacity between the lower-conductive electrode 7a and the semiconductor substrate 100 is increased and an effective electric capacity between the lower-conductive electrode 7a and the ground potential is made large since part or all of the capacitative element 7 is arranged on the gate insulating film 102. Hence, the time constant determined from the protective impedance 200 and the capacitative element 7 (Cf) is increased and the protection circuit 5 can attenuate noise to a larger extent.

Further, advantages of the flow sensor device according to Fourth Embodiment will be described.

The first to seventh advantages are similar to those in Third Embodiment.

The eighth advantage is that the sixth effect serves to prevent the insulating film between the resistive element 6 and the semiconductor substrate 100 from breaking and the protection circuit 5 can thus have an improved reliability.

A ninth advantage is that the seventh effect serves to allow the protection circuit 5 to attenuate noise to a larger extent.

### Fifth Embodiment

A flow sensor device according to Fifth Embodiment of the present invention will be described next below with reference to FIG. 5. FIG. 5 is a layout drawing illustrating a protection circuit 5 of the flow sensor device according to Fifth Embodiment. The same parts as in the previous embodiments will be respectively denoted by the same reference numbers as in the previous embodiments, and will not be described below.

The flow sensor device according to Fifth Embodiment of the present invention is characterized in that a clamp element 12 is provided between the resistive element 6 and the capacitative element 7 of the flow sensor device according to Third Embodiment.

Further, the effects of the flow sensor device according to Fifth Embodiment will be described.

The first to fifth effects are similar to those in Third Embodiment.

The sixth effect is that the clamp element 12 provided between the resistive element 6 and the capacitative element 7 can be downsized since the fifth effect serves to improve the acceptable dissipation of the resistive element 6 and the resistive element 6 therefore serves to limit a current at application of an overvoltage such as an electrostatic discharge and a surge pulse.

Further, advantages of the flow sensor device according to Fifth Embodiment will be described.

The first to seventh advantages are similar to those in Third Embodiment.

The eighth advantage is that the sixth effect serves to downsize the clamp element 12 and the chip area of the integrated circuit is reduced accordingly.

### Sixth Embodiment

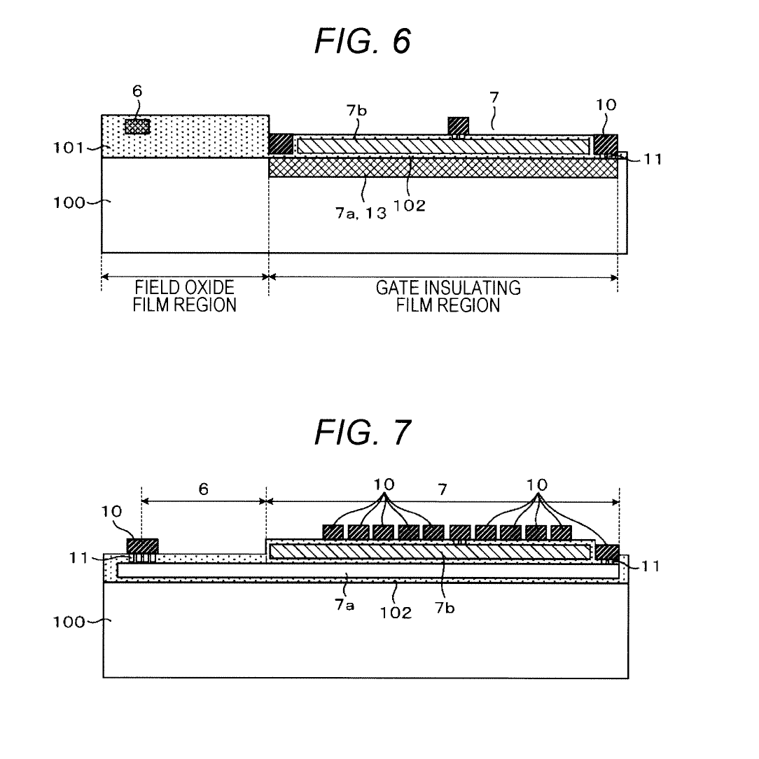

A flow sensor device according to Sixth Embodiment of the present invention will be described next below with reference to FIG. 6. FIG. 6 is a cross-sectional view of a protection circuit 5 of the flow sensor device according to Sixth Embodiment taken along line A-A′. The same parts as in the previous embodiments will be respectively denoted by the same reference numbers as in the previous embodiments, and will not be described below.

The flow sensor device according to Sixth Embodiment of the present invention is characterized in that the lower-conductive electrode 7a of the flow sensor device according to First Embodiment is formed in an impurity diffusion region 13 in the semiconductor substrate 100.

Further, the effects of the flow sensor device according to Sixth Embodiment will be described.

The first to fourth effects are similar to those in First Embodiment.

The fifth effect is that the resistances Rcf1 to Rcf4 of the lower-conductive electrode 7a can be increased by forming the lower-conductive electrode 7a in the impurity diffusion region 13. Hence, the time constant determined from the protective impedance 200 and the capacitative element 7 (Cf) is increased and the protection circuit 5 can attenuate noise to a larger extent.

Further, advantages of the flow sensor device according to Sixth Embodiment will be described.

The first to sixth advantages are similar to those in First Embodiment.

The seventh advantage is that the fifth effect serves to allow the protection circuit 5 to attenuate noise to a larger extent.

### Seventh Embodiment

A flow sensor device according to Seventh Embodiment of the present invention will be described next below with reference to FIG. 7. FIG. 7 is a cross-sectional view of a protection circuit 5 of the flow sensor device according to Seventh Embodiment taken along line A-A′. The same parts as in the previous embodiments will be respectively denoted by the same reference numbers as in the previous embodiments, and will not be described below.

The flow sensor device according to Seventh Embodiment of the present invention is characterized in that the distance of the lower-conductive electrode 7a of the flow sensor device according to Third Embodiment to the semiconductor substrate 100 is set smaller than the distance of the higher-conductive electrode 7b to the semiconductor substrate 100.

Further, the effects of the flow sensor device according to Seventh Embodiment will be described.

The first to fifth effects are similar to those in Third Embodiment.

The sixth effect is that the influence of noise from the lower-conductive electrode 7a to the peripheral circuit is suppressed since the distance of the lower-conductive electrode 7a to the semiconductor substrate 100 is set smaller than the distance of the higher-conductive electrode 7b to the semiconductor substrate 100 and the lower-conductive electrode 7a is therefore surrounded by an electromagnetic shield of the higher-conductive electrode 7b and the semiconductor substrate 100.

Further, advantages of the flow sensor device according to Seventh Embodiment will be described.

The first to seventh advantages are similar to those in Third Embodiment.

The eighth advantage is that a signal line, for example, can be provided immediately on the capacitative element 7 since the sixth effect serves to suppress influence of noise from the lower-conductive electrode 7a.

### Eighth Embodiment

A flow sensor device according to Eighth Embodiment of the present invention will be described next below with reference to FIG. 8. FIG. 8 is a layout drawing illustrating a protection circuit 5 of the flow sensor device according to Eighth Embodiment. The same parts as in the previous embodiments will be respectively denoted by the same reference numbers as in the previous embodiments, and will not be described below.

The flow sensor device according to Eighth Embodiment of the present invention is characterized in that a conductor in a spiral shape is formed as the resistive element 6 of the flow sensor device according to First Embodiment.

Further, the effects of the flow sensor device according to Eighth Embodiment will be described.

The first to fourth effects are similar to those in First Embodiment.

The fifth effect is that the time constant determined from the protective impedance 200 and the capacitative element 7 (Cf) is increased and the protection circuit 5 can attenuate noise to a larger extent since a conductor in a spiral shape is used for the resistive element 6 and the self-inductance of the resistive element 6 itself is thus increased.

Further, advantages of the flow sensor device according to Eighth Embodiment will be described.

The first to sixth advantages are similar to those in First Embodiment.

The seventh advantage is that the fifth effect serves to allow the protection circuit 5 to attenuate noise to a larger extent.

The same effects can be obtained if any one of conductors in the shapes of a solenoid, a toroidal, and a helix is used instead of the spiral-shaped conductor.

### Ninth Embodiment

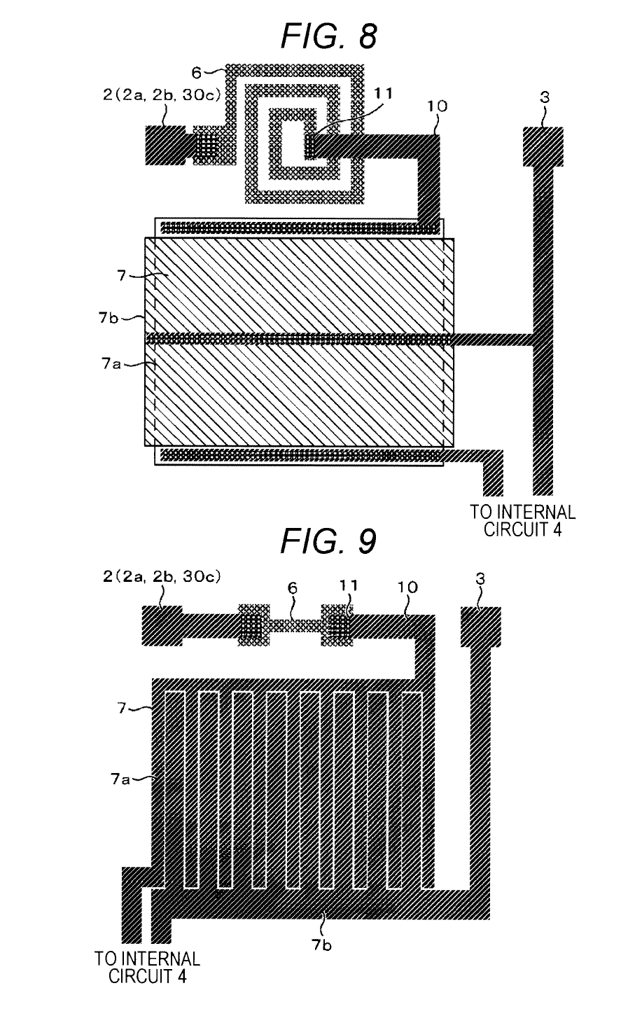

A flow sensor device according to Ninth Embodiment of the present invention will be described next below with reference to FIG. 9. FIG. 9 is a layout drawing illustrating a protection circuit 5 of the flow sensor device according to Ninth Embodiment. The same parts as in the previous embodiments will be respectively denoted by the same reference numbers as in the previous embodiments, and will not be described below.

The flow sensor device according to Ninth Embodiment of the present invention is characterized in that a pair of electrodes in the shape of comb teeth are formed to face each other so that the electrodes engage with each other as the capacitative element 7 in the flow sensor device according to First Embodiment. The lower-conductive electrode 7a and the higher-conductive electrode 7b are formed of an aluminum wiring material. The lower-conductive electrode 7a has a smaller wiring width than the higher-conductive electrode 7b and has therefore a relatively smaller conductivity than the higher-conductive electrode 7b.

Further, the effects of the flow sensor device according to Ninth Embodiment will be described.

The first to fourth effects are similar to those in First Embodiment.

The fifth effect is that the distance between the lower-conductive electrode 7a and the higher-conductive electrode 7b does not depend on the thickness of the interlayer insulating film. With this effect, the capacity of the capacitative element 7 can be controlled according to the distance between the lower-conductive electrode 7a and the higher-conductive electrode 7b, and can be increased. Hence, the time constant determined from the protective impedance 200 and the capacitative element 7 (Cf) is increased and the protection circuit 5 can attenuate noise to a larger extent.

The sixth effect is that there is a reduction in a parasitic resistance resulting from the resistances Rcf1 to Rcf8 of the capacitative element 7 of the parasitic components between the capacitative element 7 and the ground terminal 3 since the lower-conductive electrode 7a and the higher-conductive electrode 7b are formed of an aluminum wiring material. In other words, the harmful impedance 201 acting as an obstacle to escaping of noise to the ground terminal 3 is reduced, and the protection circuit 5 can attenuate noise to a larger extent.

Further, advantages of the flow sensor device according to Ninth Embodiment will be described.

The first to sixth advantages are similar to those in First Embodiment.

The seventh advantage is that the fifth effect serves to allow the protection circuit 5 to attenuate noise to a larger extent.

The eighth advantage is that the sixth effect serves to allow the protection circuit 5 to attenuate noise to a larger extent.

### Tenth Embodiment

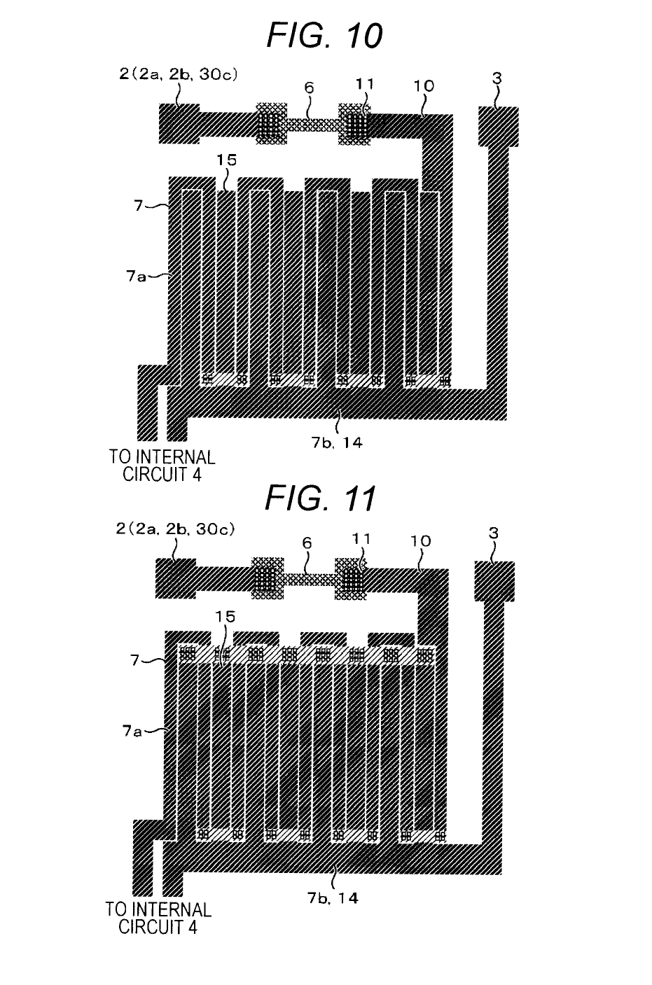

A flow sensor device according to Tenth Embodiment of the present invention will be described next below with reference to FIG. 10. FIG. 10 is a layout drawing illustrating a protection circuit 5 of the flow sensor device according to Tenth Embodiment. The same parts as in the previous embodiments will be respectively denoted by the same reference numbers as in the previous embodiments, and will not be described below.

The flow sensor device according to Tenth Embodiment of the present invention is characterized in that a lower-conductive electrode 7a in the shape of a meander is formed instead of the lower-conductive electrode 7a in the shape of comb teeth in the capacitative element 7 of the flow sensor device according to Ninth Embodiment and that teeth electrodes 15 of the higher-conductive electrode 7b in the shape of comb teeth are arranged between the lines of the lower-conductive electrode 7a in the shape of a meander.

In this embodiment, the lower-conductive electrode 7a and the higher-conductive electrode 7b are formed of an aluminum wiring material. The lower-conductive electrode 7a has a smaller wiring width than the higher-conductive electrode 7b at its electrode base part 14 and has therefore a relatively smaller conductivity than the higher-conductive electrode 7b at the electrode base part 14.

Further, the effects of the flow sensor device according to Tenth Embodiment will be described.

The first to sixth effects are similar to those in Ninth Embodiment.

The seventh effect is that the resistances Rcf1 to Rcf4 of the lower-conductive electrode 7a can be increased by forming the lower-conductive electrode 7a in the shape of a meander. That is, the time constant determined from the protective impedance 200 and the capacitative element 7 (Cf) is increased and the protection circuit 5 can attenuate noise to a larger extent.

Further, advantages of the flow sensor device according to Tenth Embodiment will be described.

The first to eighth advantages are similar to those in Ninth Embodiment.

The ninth advantage is that that the seventh effect serves to allow the protection circuit 5 to attenuate noise to a larger extent.

### Eleventh Embodiment

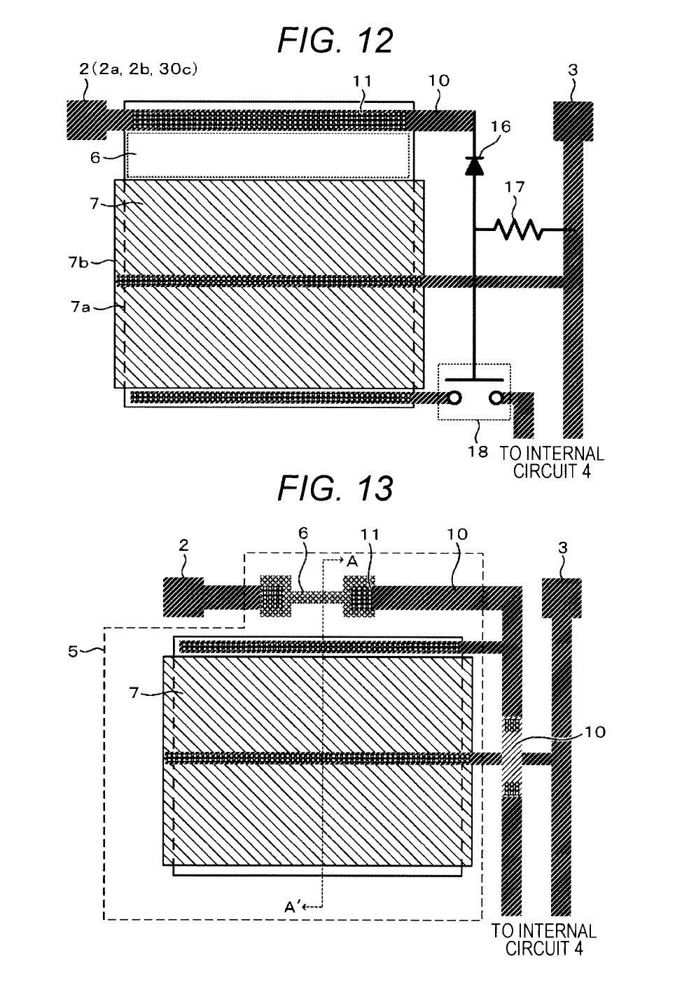

A flow sensor device according to Eleventh Embodiment of the present invention will be described next below with reference to FIG. 11. FIG. 11 is a layout drawing illustrating a protection circuit 5 of the flow sensor device according to Eleventh Embodiment. The same parts as in the previous embodiments will be respectively denoted by the same reference numbers as in the previous embodiments, and will not be described below.

The flow sensor device according to Eleventh Embodiment of the present invention is characterized in that the teeth electrodes 15 of the higher-conductive electrode 7b in the shape of comb teeth of the flow sensor device according to Tenth Embodiment are electrically connected together at the respective edges of the teeth electrodes 15 via a route different from a route for the electrode base part 14.

Further, the effects of the flow sensor device according to Eleventh Embodiment will be described.

The first to seventh effects are similar to those in Tenth Embodiment.

The eighth effect is that the resistances Rcf5 to Rcf8 of the higher-conductive electrode 7b can be reduced in a manner that the teeth electrodes 15 of the higher-conductive electrode 7b in the shape of comb teeth are electrically connected together at the respective edges of the teeth electrodes 15 via a route different from a route for the electrode base part 14. In other words, the parasitic component acting as an obstacle to escaping of to the ground terminal 3 is reduced, and the protection circuit 5 can attenuate noise to a larger extent.

Further, advantages of the flow sensor device according to Eleventh Embodiment will be described.

The first to ninth advantages are similar to those in Tenth Embodiment.

The tenth advantage is that the eighth effect serves to allow the protection circuit 5 to attenuate noise to a larger extent.

### Twelfth Embodiment

A flow sensor device according to Twelfth Embodiment of the present invention will be described next below with reference to FIG. 12. FIG. 12 is a layout drawing illustrating a protection circuit 5 of the flow sensor device according to Twelfth Embodiment. The same parts as in the previous embodiments will be respectively denoted by the same reference numbers as in the previous embodiments, and will not be described below.

The flow sensor device according to Twelfth Embodiment of the present invention is characterized in that the flow sensor device has a configuration, in addition to the configuration of the flow sensor device according to Third Embodiment, in which a rectifying element 16 and a protective resistance 17 are provided between the external terminal 2 and the ground terminal 3 and a switching element 18 is provided that controls a connection state between the capacitative element 7 and the internal circuit 4 based on the potential of the protective resistance 17 at an edge thereof near the rectifying element 16.

Further, the effects of the flow sensor device according to Twelfth Embodiment will be described.

The first to fifth effects are similar to those in Third Embodiment.

The sixth effect is that the internal circuit 4 can be prevented from breaking down due to application of an overvoltage since the switching element 18 separates the connection between the capacitative element 7 and the internal circuit 4 in a case where an overvoltage exceeding a breakdown voltage of the rectifying element 16 is applied to the external terminal 2.

Further, advantages of the flow sensor device according to Twelfth Embodiment will be described.

The first to seventh advantages are similar to those in Third Embodiment.

The eighth advantage is that the flow sensor device can have an improved reliability since the sixth effect serves to prevent the internal circuit 4 from breaking down due to an overvoltage.

As described above, when the present invention is applied to the flow sensor device provided with the protection circuit 5 that removes or attenuates electromagnetic noise, it becomes possible to improve the performance of the protection circuit 5 without increasing the number of design processes. In particular, the present invention exhibits excellent effects when the protection circuit 5 is integrated on the semiconductor substrate.

### REFERENCE SIGNS LIST

1 flow sensor device
2 external terminal
2a power source terminal
2b sensor output terminal
3 ground terminal
4 internal circuit
5, 5a to 5d protection circuit
6 resistive element
7 capacitative element
7a lower-conductive electrode
7b higher-conductive electrode
8a first connection region
8b second connection region
9 extension part
10 wiring
11 contact
12 clamp element
13 impurity diffusion region
14 electrode base part
15 teeth electrode
16 diode element
17 protective resistance
18 switching element
19 gate electrode
20 LSI
21 sensor element
22 temperature sensor
23 detection section
24 thermister
30a to 30d bonding pad
31 bonding wire
100 semiconductor substrate
101 field oxide film
102 gate insulating film
103 insulating film
200 protective impedance
201 harmful impedance

1. A sensor device comprising:
an external terminal to which an external device is connected;
a ground terminal connected to the ground;
an internal circuit that generates a sensor output signal; and
a protection circuit having a resistive element and a capacitative element between the external terminal and the internal circuit, wherein
the capacitative element is formed of a pair of electrodes having different conductivities from each other, and
a lower-conductive electrode of the electrodes which has a smaller conductivity than the other electrode is connected to the external terminal and the internal circuit.

2. The sensor device according to claim 1, wherein the lower-conductive electrode has a first connection region and a second connection region, the first connection region being electrically connected to the external terminal and the second connection region being electrically connected to the internal circuit.

3. The sensor device according to claim 1, wherein the first connection region and the second connection region are provided with a space in between.

4. The sensor device according to claim 3, wherein at least one of the first connection region and the second connection region has an extension part extending toward the other connection region.

5. The sensor device according to claim 1, wherein the resistive element is formed in a same layer as a layer where the lower-conductive electrode is formed, and communicates with the lower-conductive electrode.

6. The sensor device according to claim 5, wherein
the protection circuit is formed on a field oxide film of an insulating film and a gate insulating film over a semiconductor substrate, the gate insulating film being thinner than the field oxide film,
the resistive element is formed on the field oxide film, and
at least a part of the capacitative element is formed on the gate insulating film.

7. The sensor device according to claim 5, wherein the protection circuit has a clamp element between the resistive element and the capacitative element.

8. The sensor device according to claim 1, wherein
the protection circuit has an impurity diffusion region in a semiconductor substrate, and
the lower-conductive electrode is formed in the impurity diffusion region.

9. The sensor device according to claim 1, wherein
the protection circuit is formed on a semiconductor substrate, and
the lower-conductive electrode of the pair of the electrodes is formed near the semiconductor substrate.

10. The sensor device according to claim 1, wherein the resistive element is made using metal silicide.

11. The sensor device according to claim 1, wherein the resistive element is made using refractory metal.

12. The sensor device according to claim 1, wherein the resistive element is made of a conductor in a spiral shape.

13. The sensor device according to claim 1, wherein the resistive element is made of a conductor in a helical shape.

14. The sensor device according to claim 1, wherein
the pair of electrodes are in a shape of comb teeth, and
the pair of electrodes are formed to face each other so that a comb-teeth part of one of the electrodes engages with a comb-teeth part of the other of the electrodes.

15. The sensor device according to claim 1, wherein
one of the pair of electrodes is in a shape of a meander and the other is in a shape of comb teeth, the other electrode having a plurality of teeth electrodes protruded in a shape of comb teeth from a base part of the other electrode, and
the teeth electrodes are arranged between lines of the meander electrode.

16. The sensor device according to claim 15, wherein the teeth electrodes of the comb-teeth electrode are electrically connected together at respective edges of the teeth electrodes via a route different from a route for the electrode base part.

17. The sensor device according to claim 1, wherein
the protection circuit includes:
a rectifying element;
a protective resistance connecting the rectifying element and the ground terminal together; and
a switching element that controls connection between the capacitative element and the internal circuit, and
the switching element controls connection between the capacitative element and the internal circuit based on a potential of the protective resistance at an edge of the protective resistance near the rectifying element.
